(19) United States
(12) Patent Application Publication
(10) Pub. No.: US 2026/0006879 A1
(43) Pub. Date: Jan. 1, 2026

(54) SEMICONDUCTOR STRUCTURE AND MANUFACTURING METHOD THEREOF

(71) Applicant: United Microelectronics Corp., Hsinchu (TW)

(72) Inventor: Po-Yu Yang, Hsinchu City (TW)

(73) Assignee: United Microelectronics Corp., Hsinchu (TW)

(21) Appl. No.: 18/784,969

(22) Filed: Jul. 26, 2024

(30) Foreign Application Priority Data
Jun. 26, 2024 (TW) 113123779

(51) Int. Cl. H01L 29/66; H01L 21/266; H01L 29/78

(52) U.S. Cl. CPC H10D 64/017; H01L 21/266; H10D 30/0227; H10D 30/601

(57) ABSTRACT

A semiconductor structure includes a substrate, a gate structure on the substrate, a source region, and a drain region. The gate structure includes a gate, a gate insulation layer between the gate and the substrate, a spacer on the substrate and adjacent to the gate, and an insulation feature disposed between a lower gate and the spacer and overlapping an upper gate in the normal direction of the substrate. The gate includes the upper and lower gates overlapping in a normal direction of the substrate, and in a first direction a length of the upper gate is greater than a length of the lower gate. The source region is disposed in the substrate and located on one side of the gate structure. The drain region is disposed in the substrate and located on the other side of the gate structure. A manufacturing method of a semiconductor structure is also provided.

### CROSS-REFERENCE TO RELATED APPLICATION

This application claims the priority benefit of Taiwan application serial no. 113123779, filed on Jun. 26, 2024. The entirety of the above-mentioned patent application is hereby incorporated by reference herein and made a part of this specification.

### BACKGROUND

### Technical Field

The disclosure relates to a semiconductor device and a manufacturing method thereof; more particularly, the disclosure relates to a transistor structure and a manufacturing method thereof.

### Description of Related Art

In a conventional medium-voltage semiconductor device, the electric field strength in a doped region beneath an edge of a transistor is relatively high, which renders this area susceptible to hot carrier injection (HCI) phenomena, thereby compromising the reliability of the semiconductor device. Additionally, the transistor in the medium-voltage semiconductor device frequently generates excessive off-state current due to significant gate induced drain leakage (GIDL), adversely impacting the electrical performance of the semiconductor device.

### SUMMARY

The disclosure provides a semiconductor structure with relatively good reliability and/or electrical performance.

Some embodiments of the disclosure provide a semiconductor structure which includes a substrate, a gate structure, a source region, and a drain region. The gate structure is disposed on the substrate and includes a gate, a gate insulation layer, a spacer, and an insulation feature. The gate includes an upper gate and a lower gate, where the upper gate and the lower gate overlap in a normal direction of the substrate, and a length of the upper gate in a first direction is greater than a length of the lower gate in the first direction. The gate insulation layer is disposed between the gate and the substrate. The spacer is disposed on the substrate and adjacent to the gate. The insulation feature is disposed between the lower gate and the spacer, where the insulation feature and the upper gate overlap in the normal direction of the substrate. The source region is disposed in the substrate and located on one side of the gate structure. The drain region is disposed in the substrate and located on the other side of the gate structure.

The disclosure provides a manufacturing method of a semiconductor structure, by performing which a semiconductor structure with relatively good reliability and/or electrical performance may be formed.

Some other embodiments of the disclosure provide a manufacturing method of a semiconductor structure, which includes the following steps. An isolation structure is formed in the substrate. A gate insulation layer and a dummy gate are formed on the substrate by applying a mask, where a length of the mask in a first direction is greater than a length of the gate insulation layer and the dummy gate in the first direction. An insulation feature is formed on the substrate, where the insulation feature and the mask overlap in a normal direction of the substrate. A spacer is formed on the substrate, where the spacer is disposed on side surfaces of the mask and the insulation feature. A source region and a drain region are formed in the substrate, where the source region and the drain region are located between the insulation feature and the isolation structure. The dummy gate is replaced with a gate.

Based on the above, in the semiconductor structure and a manufacturing method thereof provided in one or more embodiments of this disclosure, by making the length of the upper gate in the gate greater than the length of the lower gate and by disposing the insulation feature on the side of the gate facing the drain region, the distance between the gate and the drain region may relatively increase. This may reduce the electric field strength of the doped regions located below the spacer and the insulation feature, thereby reducing the possibility of HCI and allowing the semiconductor structure provided in one or more embodiments of this disclosure to have relatively good reliability. Moreover, as the distance between the gate and the drain region increases, the GIDL may also be relatively reduced, thus lowering the off-state current of the gate structure in the semiconductor structure provided in one or more embodiments of this disclosure and further improving the electrical performance of the semiconductor structure provided in one or more embodiments of this disclosure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1J are schematic views illustrating a process of a manufacturing method of a semiconductor structure according to a first embodiment of the disclosure.

FIG. 2A to FIG. 2J are schematic views illustrating a process of a manufacturing method of a semiconductor structure according to a second embodiment of the disclosure.

### DESCRIPTION OF THE EMBODIMENTS

Reference is now made in detail to exemplary embodiments of the disclosure, and examples of the exemplary embodiments are described in the accompanying drawings. Whenever possible, the same reference numbers are used in the drawings and descriptions to indicate the same or similar parts.

In the following embodiments, a first conductive type is a P-type, and a second conductive type is an N-type, which should however not be construed as a limitation in the disclosure. In other embodiments, the first conductive type may be the N-type, and the second conductive type may be the P-type. A P-type dopant is, for instance, boron, and an N-type dopant is, for instance, phosphorus or arsenic.

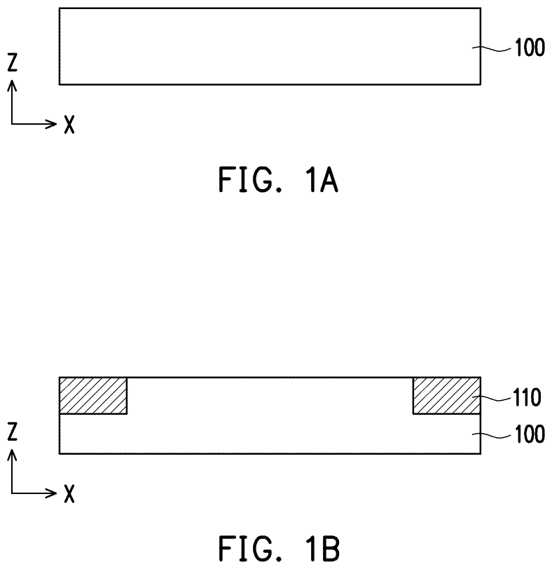

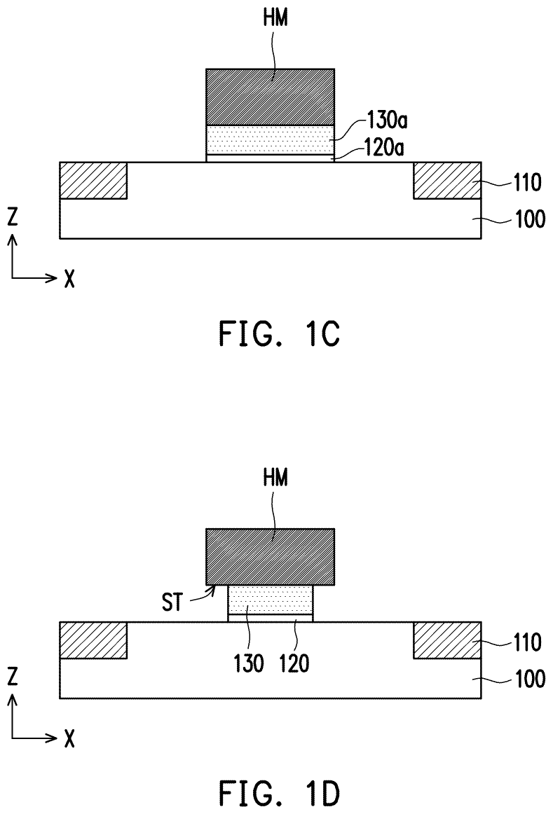

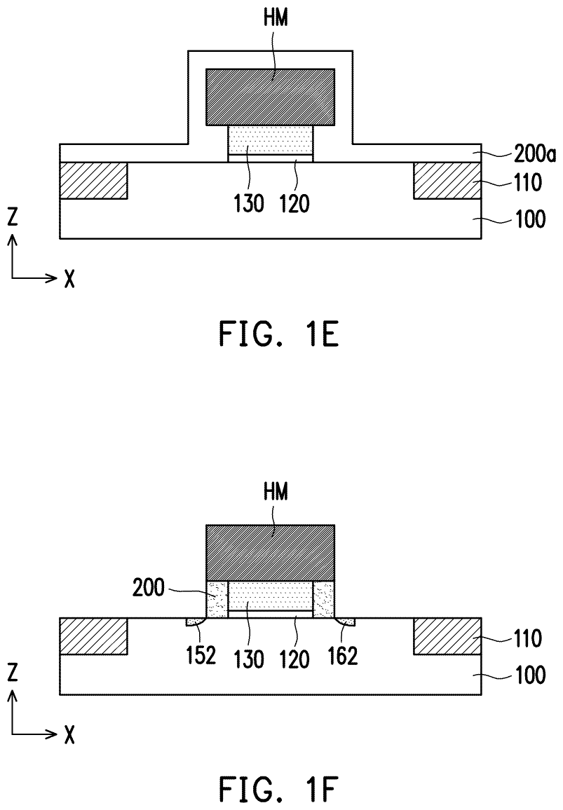

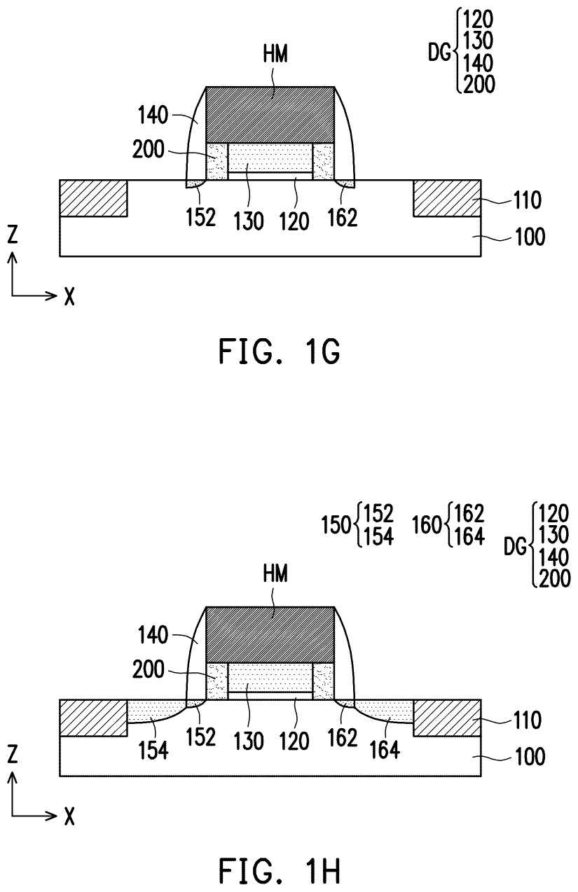

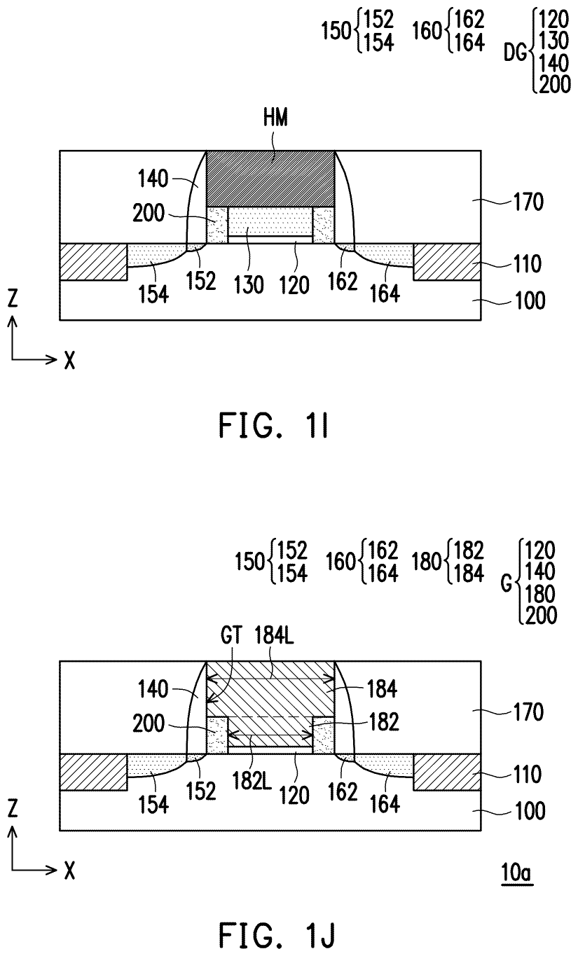

FIG. 1A to FIG. 1J are schematic views illustrating a process of a manufacturing method of a semiconductor structure according to a first embodiment of the disclosure.

With reference to FIG. 1A to FIG. 1J, in this embodiment, the semiconductor structure 10a may be formed by performing following steps, which should however not be construed as a limitation in the disclosure.

Step (1) is performed to provide a substrate 100.

With reference to FIG. 1A, in some embodiments, the substrate 100 may be a semiconductor substrate, which should however not be construed as a limitation in the disclosure. A material of the substrate 100 may include, for instance, elemental semiconductors, compound semiconductors, alloy semiconductors, or other appropriate materials. For instance, the material of the substrate 100 may include silicon, germanium, indium antimonide, indium arsenide, indium phosphide, gallium nitride, gallium arsenide, gallium antimonide, lead telluride, or combinations thereof. In other embodiments, the substrate 100 may be a silicon on insulator (SOI) substrate. In some embodiments, the substrate 100 may include a deep well region (not shown) having a first conductive type. For instance, the substrate 100 may be a P-type substrate, which should however not be construed as a limitation in the disclosure.

Step (2) is performed to form an isolation structure 110 in the substrate 100.

With reference to FIG. 1B, in some embodiments, the isolation structure 110 may be formed by first performing an etching process to form a plurality of trenches in the substrate 100 and then performing a chemical vapor deposition (CVD) process to form an insulation material in the trenches, which should however not be construed as a limitation in the disclosure. In some embodiments, the isolation structure 110 may include shallow trench isolation structures. A material of the isolation structure 110 may include, for instance, undoped silicon oxide, silicon nitride, or a combination thereof, which should however not be construed as a limitation in the disclosure.

Step (3) is performed to form a gate insulation material layer 120a and a dummy gate material layer 130a on the substrate 100.

With reference to FIG. 1C, in this embodiment, a mask HM may serve to form the gate insulation material layer 120a and the dummy gate material layer 130a. Specifically, a gate insulation material layer and a dummy gate material layer may be first formed sequentially and entirely on the substrate 100, and then an etching process may be performed on the gate insulation material layer and the dummy gate material layer by applying the mask HM to form the gate insulation material layer 120a and the dummy gate material layer 130a, respectively, which should however not be construed as a limitation in the disclosure.

In some embodiments, the gate insulation material layer 120a may be formed on the substrate 100 by performing a CVD process or a thermal oxidation process, which should however not be construed as a limitation in the disclosure. A material of the gate insulation material layer 120a may include, for instance, appropriate dielectric materials. For instance, the material of the gate insulation material layer 120a may include silicon oxide (SiO₂), silicon nitride (Si₃N₄), aluminum oxide (Al₂O₃), tantalum oxide (Ta₂O₅), titanium oxide (TiO₂), zinc oxide (ZnO₂), and hafnium oxide (HfO₂), which should however not be construed as a limitation in the disclosure.

In some embodiments, the dummy gate material layer 130a may be formed on the gate insulation material layer 120a by performing a CVD process or a thermal oxidation process, which should however not be construed as a limitation in the disclosure. A material of the dummy gate material layer 130a may include, for instance, polysilicon, which should however not be construed as a limitation in the disclosure.

Step (4) is performed to form a gate insulation layer 120 and a dummy gate 130 on the substrate 100.

With reference to FIG. 1D, in this embodiment, the mask HM may be applied again to form the gate insulation layer 120 and the dummy gate 130. Specifically, a lateral etching process may be performed on the gate insulation material layer 120a and the dummy gate material layer 130a by applying the mask HM to remove a portion of the gate insulation material layer 120a and the dummy gate material layer 130a, thereby forming the gate insulation layer 120 and the dummy gate 130, respectively. In some embodiments, the lateral etching process includes a wet etching process, which should however not be construed as a limitation in the disclosure.

From another perspective, after removing a portion of the gate insulation material layer 120a and the dummy gate material layer 130a by performing the lateral etching process, a lateral groove ST is formed. In light of the above, in this embodiment, a length of the mask HM in an X direction is greater than respective lengths of the gate insulation layer 120 and the dummy gate 130 in the X direction.

In this embodiment, by performing the lateral etching process on the gate insulation material layer 120a and the dummy gate material layer 130a, a length of the subsequently formed gate 180 in the X direction may be defined.

Step (5) is performed to form an insulation feature material layer 200a on the substrate 100.

With reference to FIG. 1E, in some embodiments, the insulation feature material layer 200a may be formed on the substrate 100 by performing a CVD process, which should however not be construed as a limitation in the disclosure. The insulation feature material layer 200a may include, for instance, appropriate insulation materials. For instance, the material of the insulation feature material layer 200a may include silicon oxide, which should however not be construed as a limitation in the disclosure. In this embodiment, the insulation feature material layer 200a covers the mask HM, the gate insulation layer 120, and the dummy gate 130 and fills the lateral groove ST, which should however not be construed as a limitation in the disclosure.

Step (6) is performed to form an insulation feature 200 on the substrate 100.

With reference to FIG. 1F, in this embodiment, the insulation feature 200 may be formed by performing an etching process on the insulation feature material layer 200a. Specifically, an anisotropic etching process may be performed to remove the insulation feature material layer 200a located outside the lateral groove ST, thereby forming the insulation feature 200 located in the lateral groove ST, which should however not be construed as a limitation in the disclosure.

From another perspective, the insulation feature 200 and the mask HM overlap in anormal direction Z of the substrate 100.

In this embodiment, steps of forming the semiconductor structure 10a may further include forming a lightly doped source region 152 and a light doping drain region 162 in the substrate 100. Specifically, the lightly doped source region 152 and the light doping drain region 162 may be formed in the substrate 100 by first performing an ion implantation process followed by a thermal treatment process, which should however not be construed as a limitation in the disclosure. In some embodiments, the lightly doped source region 152 and the light doping drain region 162 may have a second conductivity type. For instance, in this embodiment, the lightly doped source region 152 and the light doping drain region 162 may be an N-type lightly doped source region and an N-type light doping drain region, respectively, which should however not be construed as a limitation in the disclosure.

Step (7) is performed to form a spacer 140 on the substrate 100.

With reference to FIG. 1G, in some embodiments, the spacer 140 may be formed on the substrate 100 by performing a CVD process, which should however not be construed as a limitation in the disclosure. The spacer 140 may include, for instance, appropriate insulation materials. For instance, the material of the spacer 140 may include silicon oxide, which should however not be construed as a limitation in the disclosure. In this embodiment, the spacer 140 is disposed on side surfaces of the mask HM and the insulation feature 200, which should however not be construed as a limitation in the disclosure. In this embodiment, the spacer 140 may cover the lightly doped source region 152 and the light doping drain region 162 located in the substrate 100, which should however not be construed as a limitation in the disclosure.

In this embodiment, the gate insulation layer 120, the dummy gate 130, the insulation feature 200, and the spacer 140 may constitute a dummy gate structure DG, which should however not be construed as a limitation in the disclosure.

Step (8) is performed to form a source region 150 and a drain region 160 in the substrate 100.

With reference to FIG. 1H, specifically, in this embodiment, steps of forming the semiconductor structure 10a may further include forming a heavily doped source region 154 and a heavily doped drain region 164 in the substrate 100. In some embodiments, the heavily doped source region 154 and the heavily doped drain region 164 may be formed in the substrate 100 by first performing an ion implantation process followed by a thermal treatment process, which should however not be construed as a limitation in the disclosure. In some embodiments, the heavily doped source region 154 and the heavily doped drain region 164 may have a second conductivity type. For instance, in this embodiment, the heavily doped source region 154 and the heavily doped drain region 164 may be an N-type heavily doped source region and an N-type heavily doped drain region, respectively, which should however not be construed as a limitation in the disclosure.

In this embodiment, the heavily doped source region 154 is adjacent to the lightly doped source region 152, and the heavily doped drain region 164 is adjacent to the light doping drain region 162. From another perspective, the heavily doped source region 154 is disposed between the lightly doped source region 152 and the isolation structure 110, and the heavily doped drain region 164 is disposed between the light doping drain region 162 and the isolation structure 110.

In this embodiment, the source region 150 includes the lightly doped source region 152 and the heavily doped source region 154, and the drain region 160 includes the light doping drain region 162 and the heavily doped drain region 164, which should however not be construed as a limitation in the disclosure. The source region 150 is, for instance, disposed between the insulation feature 200 and the isolation structure 110, and the drain region 160 is, for instance, disposed between another insulation feature 200 and another isolation structure 110, which should however not be construed as a limitation in the disclosure.

Step (9) is performed to form an insulation layer 170 on the substrate 100.

With reference to FIG. 1I, in some embodiments, the insulation layer 170 may be formed on the substrate 100 by performing a CVD process and a planarization process. Specifically, an insulation material layer (not shown) covering the dummy gate structure DG may be first formed by performing a CVD process, and then a chemical mechanical polishing (CMP) process may be performed on the insulation material layer to form the insulation layer 170, where a top surface of the insulation layer 170 is substantially coplanar with a top surface of the mask HM, which should however not be construed as a limitation in the disclosure.

Step (10) is performed to replace the dummy gate 130 with a gate 180.

With reference to FIG. 1J, in some embodiments, the dummy gate 130 may be replaced with the gate 180 by performing a replacement metal gate (RMG) process. Specifically, an etching process may be first performed to remove the mask HM and the dummy gate 130 to form a gate groove GT, and then a CVD process, a physical vapor deposition (PVD) process, or an atomic layer deposition (ALD) process may be performed to form the gate 180 in the gate groove GT. A material of the gate 180 may include, for instance, appropriate metal or metal alloys. For instance, the material of the gate 180 may include copper (Cu), aluminum (Al), tungsten (W), nickel (Ni), cobalt (Co), or combinations thereof, which should however not be construed as a limitation in the disclosure.

In this embodiment, the gate insulation layer 120, the gate 180, the insulation feature 200, and the spacer 140 may constitute a gate structure G, which should however not be construed as a limitation in the disclosure.

At this point, the manufacturing method of the semiconductor structure 10a provided in this embodiment is completed, which should however not be construed as a limitation in the manufacturing method of the semiconductor structure 10a provided in the disclosure. In this embodiment, through the arrangement of the insulation feature 200, the distance between the gate 180 and the source region 150 and the drain region 160 may relatively increase, thereby reducing the electric field strength of the doped regions located below the spacer 140 and the insulation feature 200, so as to reduce the possibility of HCI. Moreover, as the distance between the gate 180 and the drain region 160 increases, the GIDL may also be relatively reduced, thereby reducing the off-state current of the gate structure G.

The structure of the semiconductor structure 10a provided in this embodiment will be briefly introduced below with reference to FIG. 1J, which should however not be construed as a limitation in the disclosure.

With reference to FIG. 1J, the semiconductor structure 10a provided in this embodiment includes the substrate 100, the isolation structure 110, the gate structure G, the source region 150, and the drain region 160.

The substrate 100, for instance, has a first conductive type. For instance, the substrate 100 may be a P-type substrate, which should however not be construed as a limitation in the disclosure. Other descriptions of the substrate 100 may be referred to as those provided in the previous embodiment and will not be repeated hereinafter.

The isolation structure 110 is, for instance, disposed in the substrate 100. Other descriptions of the isolation structure 110 may be referred to as those provided in the previous embodiment and will not be repeated hereinafter.

The gate structure G is, for instance, disposed on the substrate 100, and is, for instance, located between adjacent isolation structures 110. In this embodiment, the gate structure G is a planar gate structure and includes the gate 180, the gate insulation layer 120, the insulation feature 200, and the spacer 140.

The gate 180 includes, for instance, a lower gate 182 and an upper gate 184, where the lower gate 182 and the upper gate 184 overlap in the normal direction Z of the substrate 100. A size of the upper gate 184 is, for instance, greater than a size of the lower gate 182, such that the gate 180 may have, for instance, an inverted T-shape in the cross-sectional view shown in FIG. 1J. Specifically, in this embodiment, a length 184L of the upper gate 184 in the X direction is greater than a length 182L of the lower gate 182 in the X direction. A ratio of the length 184L of the upper gate 184 to the length 182L of the lower gate 182 may be, for instance, 1:0.5-1:0.9, which should however not be construed as a limitation in the disclosure. In some embodiments, a length 182W of the lower gate 182 in the X direction may be 0.03 μm to 1 μm, which should however not be construed as a limitation in the disclosure. From another perspective, the gate 180 includes two lateral grooves ST extending in the X direction. Other descriptions of the gate 180 may be referred to as those provided in the previous embodiment and will not be repeated hereinafter.

The gate insulation layer 120 is, for instance, disposed between the gate 180 and the substrate 100. Other descriptions of the gate insulation layer 120 may be referred to as those provided in the previous embodiment and will not be repeated hereinafter.

The spacer 140 is, for instance, disposed on the substrate 100 and adjacent to the gate 180. Other descriptions of the spacer 140 may be referred to as those provided in the previous embodiment and will not be repeated hereinafter.

The insulation feature 200 is, for instance, disposed between the lower gate 182 and the spacer 140. In this embodiment, the insulation feature 200 and the upper gate 184 also overlap in the normal direction Z of the substrate 100. From another perspective, the insulation feature 200, for instance, fills the two lateral grooves ST of the gate 180. Other descriptions of the insulation feature 200 may be referred to as those provided in the previous embodiment and will not be repeated hereinafter.

The source region 150 is, for instance, disposed in the substrate 100 and is, for instance, located on one side of the gate structure G. In this embodiment, the source region 150 includes the lightly doped source region 152 and the heavily doped source region 154. The lightly doped source region 152 and the spacer 140 overlap in the normal direction Z of the substrate 100, for instance. The heavily doped source region 154 is, for instance, adjacent to the lightly doped source region 152. The source region 150 has, for instance, a second conductivity type. For instance, the source region 150 may be an N-type source region, which should however not be construed as a limitation in the disclosure. Other descriptions of the source region 150 may be referred to as those provided in the previous embodiment and will not be repeated hereinafter.

The drain region 160 is, for instance, disposed in the substrate 100 and is, for instance, located on the other side of the gate structure G. In this embodiment, the drain region 160 includes the lightly doped drain region 162 and the heavily doped drain region 164. The lightly doped drain region 162 and the spacer 140 overlap in the normal direction Z of the substrate 100, for instance. The heavily doped drain region 164 is, for instance, adjacent to the lightly doped drain region 162. The drain region 160 has, for instance, a second conductivity type. For instance, the drain region 160 may be an N-type drain region, which should however not be construed as a limitation in the disclosure. Other descriptions of the drain region 160 may be referred to as those provided in the previous embodiment and will not be repeated hereinafter.

In this embodiment, the semiconductor structure 10a further includes the insulation layer 170. The insulation layer 170 is, for instance, disposed on the substrate 100 and covers the isolation structure 110. In some embodiments, the top surface of the insulation layer 170 is substantially coplanar with the top surface of the gate 180 in the gate structure G, which should however not be construed as a limitation in the disclosure.

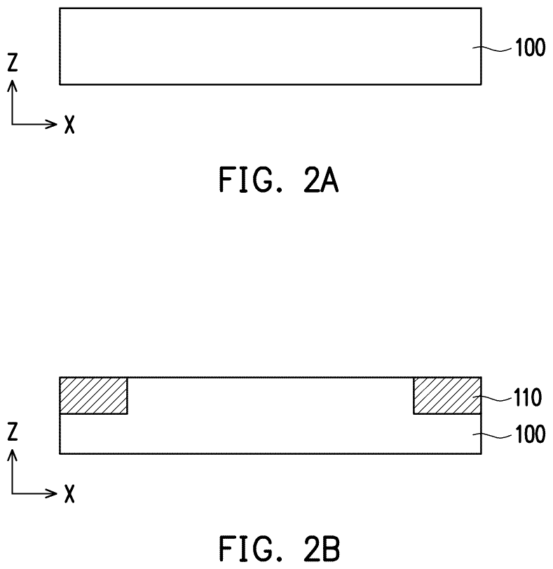

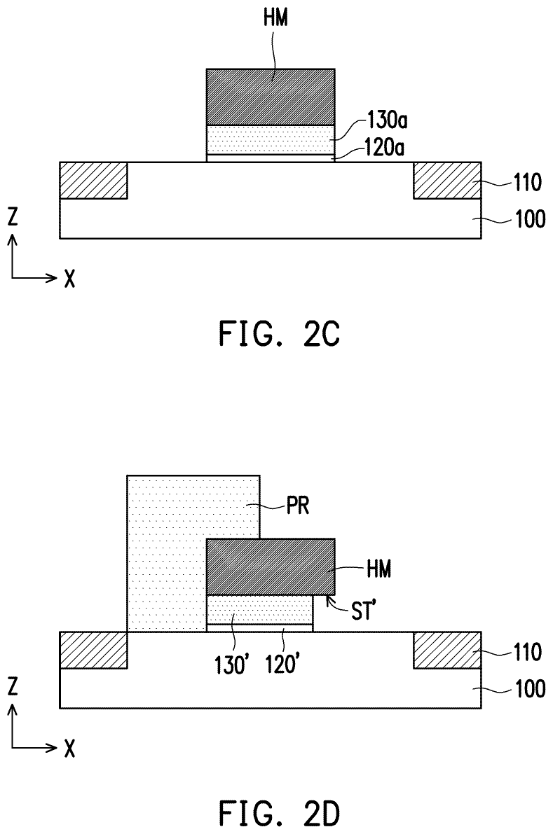

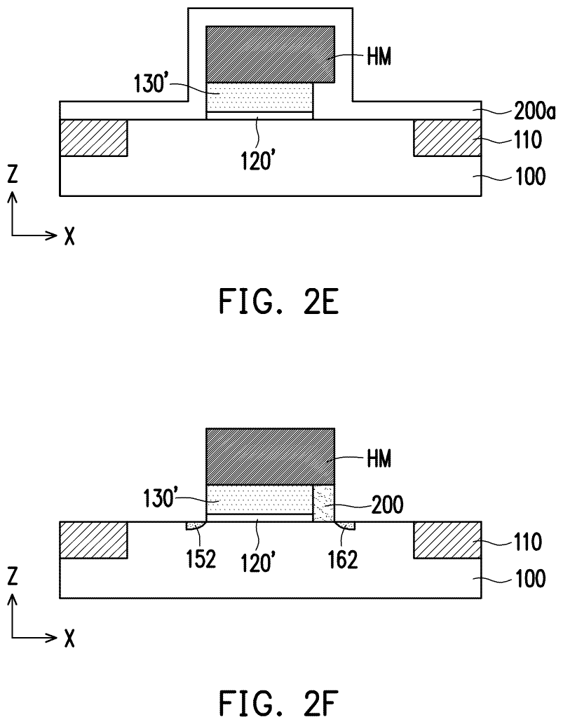

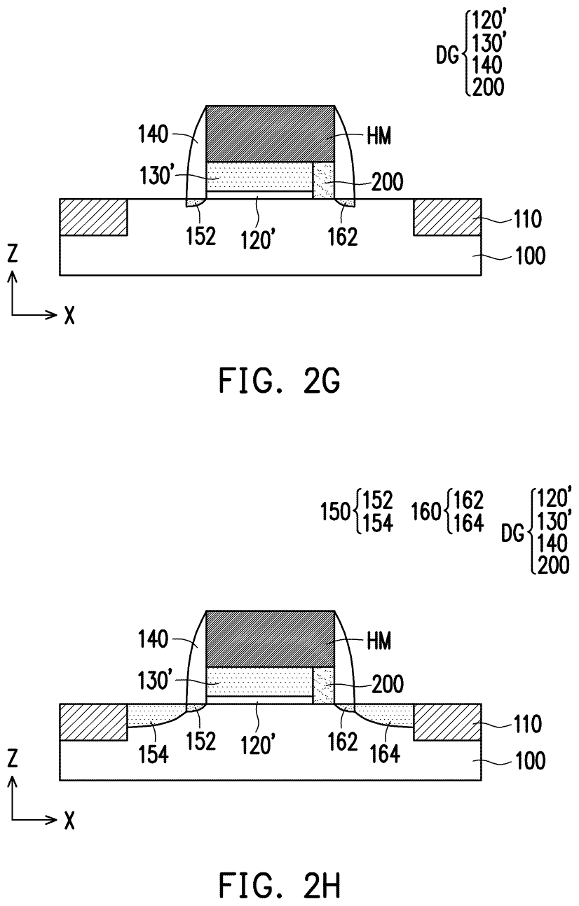

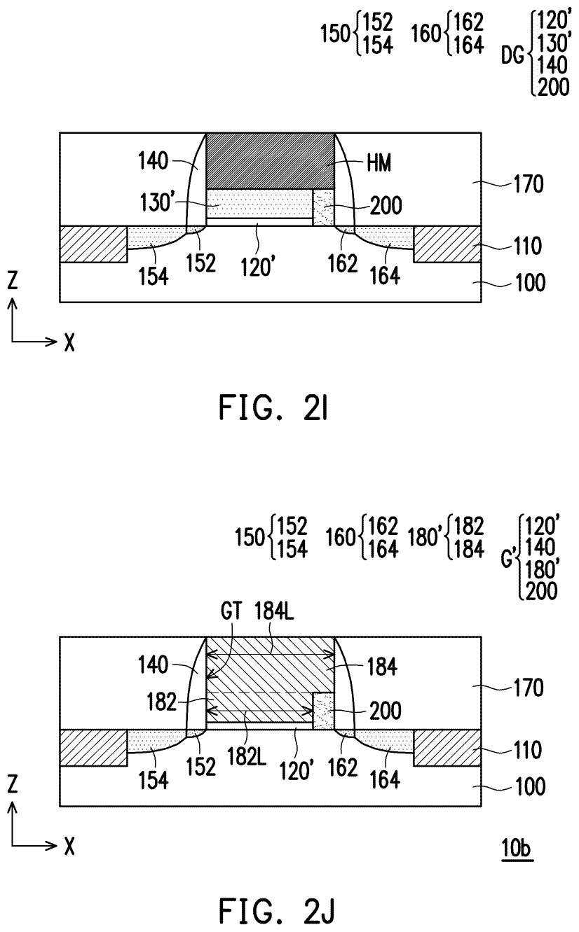

FIG. 2A to FIG. 2J are schematic views illustrating a process of a manufacturing method of a semiconductor structure according to a second embodiment of the disclosure. It should be noted that reference numbers and partial content of the embodiments depicted in FIG. 2A to FIG. 2J may be derived from those depicted in FIG. 1A to FIG. 1J, where the same or similar reference numbers serve to represent the same or similar elements, and the explanation of the same technical content is omitted.

With reference to FIG. 2A to FIG. 2J, in this embodiment, a semiconductor structure 10b may be formed by performing following steps, which should however not be construed as a limitation in the disclosure.

Steps (1) to (3) are performed to provide the substrate 100form an isolation structure 110 in the substrate 100, and form a gate insulation material layer 120a and a dummy gate material layer 130a on the substrate 100. Other descriptions of steps (1) to (3) may be referred to as those provided in the previous embodiment and will not be repeated hereinafter.

Step (4′) is performed to form a gate insulation layer 120′ and a dummy gate 130′ on the substrate 100.

With reference to FIG. 2D, in this embodiment, the gate insulation layer 120′ and the dummy gate 130′ may be formed by applying a photoresist PR and a mask HM. Specifically, the photoresist PR may first be formed on the mask HM, where the photoresist PR covers sidewalls on one side of the mask HM, the gate insulation material layer 120a, and the dummy gate material layer 130a. Then, by applying the mask HM, a lateral etching process is performed on the gate insulation material layer 120a and the dummy gate material layer 130a to remove a portion of the gate insulation material layer 120a and the dummy gate material layer 130a that is not covered by the photoresist PR, thereby forming the gate insulation layer 120′ and the dummy gate 130′, respectively. In some embodiments, the lateral etching process includes a wet etching process, which should however not be construed as a limitation in the disclosure.

From another perspective, after removing the portion of the gate insulation material layer 120a and the dummy gate material layer 130a that is not covered by the photoresist PR, a lateral groove ST′ is formed.

In this embodiment, by performing the lateral etching process on the gate insulation material layer 120a and the dummy gate material layer 130a, a length of the subsequently formed gate 180′ in the X direction may be defined.

Steps (5) to (10) are performed to form the insulation feature material layer 200a on the substrate 100, form the insulation feature 200 on the substrate 100, form the spacer 140 on the substrate 100, form the source region 150 and the drain region 160 in the substrate 100, form the insulation layer 170 on the substrate 100, and replace the dummy gate 130 with the gate 180′. Other descriptions of steps (5) to (10) may be referred to as those provided in the previous embodiment and will not be repeated hereinafter.

At this point, the manufacturing method of the semiconductor structure 10b provided in this embodiment is completed, which should however not be construed as a limitation in the manufacturing method of the semiconductor structure 10b provided in the disclosure. In this embodiment, through the arrangement of the insulation feature 200, the distance between the gate 180′ and the drain region 160 may relatively increase, thereby reducing the electric field strength of the doped regions located below the spacer 140 and the insulation feature 200, so as to reduce the possibility of HCI. Moreover, as the distance between the gate 180′ and the drain region 160 increases, the GIDL may also be relatively reduced, thus lowering the off-state current of the gate structure G′.

The structure of the semiconductor structure 10b provided in this embodiment will be briefly introduced below with reference to FIG. 2J, which should however not be construed as a limitation in the disclosure.

With reference to FIG. 2J, the semiconductor structure 10b provided in this embodiment includes the substrate 100, the isolation structure 110, the gate structure G′, the source region 150, and the drain region 160. It should be noted that descriptions of the elements in the semiconductor structure 10b may be derived from the descriptions of the elements in the semiconductor structure 10a, where the explanation of identical technical content is omitted.

In this embodiment, the main difference between the semiconductor structure 10b and the semiconductor structure 10a lies in that the insulation feature 200 fills the lateral groove ST′ extending in the X direction on one side of the gate 180′.

Specifically, the gate 180′ has the lateral groove ST′ simply in the direction facing the drain region 160, which should however not be construed as a limitation in the disclosure.

From another perspective, the distance between the gate 180′ and the drain region 160 in the X direction is greater than the distance between the gate 180′ and the source region 150 in the X direction, which should however not be construed as a limitation in the disclosure.

To sum up, in the semiconductor structure and the manufacturing method thereof provided in one or more embodiments of this disclosure, by making the length of the upper gate in the gate greater than the length of the lower gate and disposing the insulation feature on one side of the gate facing the drain region, the distance between the gate and the drain region may relatively increase. This may reduce the electric field strength of the doped regions located below the spacer and the insulation feature, thereby reducing the possibility of HCI and enabling the semiconductor structure provided in one or more embodiments of this disclosure to have relatively good reliability. Moreover, as the distance between the gate and the drain region increases, the GIDL may also be relatively reduced, thus lowering the off-state current of the gate structure in the semiconductor structure provided in one or more embodiments of this disclosure and further enhancing the electrical performance of the semiconductor structure provided in one or more embodiments of this disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate;
a gate structure, disposed on the substrate and comprising:
a gate, comprising a lower gate and an upper gate, wherein the lower gate and the upper gate overlap in a normal direction of the substrate, and a length of the upper gate in a first direction is greater than a length of the lower gate in the first direction;
a gate insulation layer, disposed between the gate and the substrate;
a spacer, disposed on the substrate and adjacent to the gate; and
an insulation feature, disposed between the lower gate and the spacer, wherein the insulation feature and the upper gate overlap in the normal direction of the substrate;
a source region, disposed in the substrate and located on one side of the gate structure; and
a drain region, disposed in the substrate and located on the other side of the gate structure.

2. The semiconductor structure according to claim 1, wherein a ratio of the length of the upper gate to the length of the lower gate is 1:0.5-1:0.9.

3. The semiconductor structure according to claim 1, wherein the length of the lower gate in the first direction is 0.03 μm to 1 μm.

4. The semiconductor structure according to claim 1, wherein the source region comprises:
a lightly doped source region, overlapping the spacer in the normal direction of the substrate; and
a heavily doped source region, adjacent to the lightly doped source region.

5. The semiconductor structure according to claim 1, wherein the drain region comprises:
a lightly doped drain region, overlapping the spacer in the normal direction of the substrate; and
a heavily doped drain region, adjacent to the lightly doped drain region.

6. The semiconductor structure according to claim 5, wherein the lightly doped drain region is located between the heavily doped drain region and the insulation feature.

7. The semiconductor structure according to claim 1, wherein a distance between the gate and the drain region in the first direction is greater than a distance between the gate and the source region in the first direction.

8. A manufacturing method of a semiconductor structure, comprising:
forming an isolation structure in a substrate;
forming a gate insulation layer and a dummy gate on the substrate by applying a mask, wherein a length of the mask in a first direction is greater than a length of the gate insulation layer and the dummy gate in the first direction;
forming an insulation feature on the substrate, wherein the insulation feature and the mask overlap in a normal direction of the substrate;
forming a spacer on the substrate, wherein the spacer is disposed on side surfaces of the mask and the insulation feature;
forming a source region and a drain region in the substrate, wherein the source region and the drain region are located between the insulation feature and the isolation structure; and
replacing the dummy gate with a gate.

9. The manufacturing method according to claim 8, wherein the step of forming the gate insulation layer and the dummy gate on the substrate by applying the mask comprises:
sequentially forming a first gate insulation material layer and a first dummy gate material layer on the substrate;
performing an etching process on the first gate insulation material layer and the first dummy gate material layer by applying the mask to form a second gate insulation material layer and a second dummy gate material layer; and
performing a lateral etching process on the second gate insulation material layer and the second dummy gate material layer by applying the mask.

10. The manufacturing method according to claim 8, further comprising forming the gate insulation layer and the dummy gate on the substrate by applying a photoresist.

11. The manufacturing method according to claim 10, wherein the step of forming the gate insulation layer and the dummy gate on the substrate by applying the mask and the photoresist comprises:
sequentially forming a first gate insulation material layer and a first dummy gate material layer on the substrate;
performing an etching process on the first gate insulation material layer and the first dummy gate material layer by applying the mask to form a second gate insulation material layer and a second dummy gate material layer;
forming the photoresist on the mask, wherein the photoresist covers the mask and sidewalls on one side of the second gate insulation material layer and on one side of the second dummy gate material layer; and
performing a lateral etching process on the second gate insulation material layer and the second dummy gate material layer that are not covered by the photoresist by applying the mask.

12. The manufacturing method according to claim 8, wherein the step of forming the insulation feature on the substrate comprises:
forming an insulation feature material layer on the substrate, wherein the insulation feature material layer covers the mask, the gate insulation layer, and the dummy gate; and
performing an etching process on the insulation feature material layer by applying the mask.

13. The manufacturing method according to claim 8, wherein the step of forming the source region and the drain region in the substrate comprises:
forming a lightly doped source region and a lightly doped drain region in the substrate; and
forming a heavily doped source region and a heavily doped drain region in the substrate, wherein the heavily doped source region is adjacent to the lightly doped source region, and the heavily doped drain region is adjacent to the lightly doped drain region.

14. The manufacturing method according to claim 8, wherein the step of replacing the dummy gate with the gate comprises:
performing an etching process to remove the mask and the dummy gate to form a gate groove; and
forming the gate in the gate groove.
